(19) United States
(12) Patent Application Publication
(10) Pub. No.: US 2026/0164762 A1
(43) Pub. Date: Jun. 11, 2026

(54) METHOD AND DEVICE FOR REDUCING DAMAGE TO NANOSHEETS IN STI PROCESSING

(71) Applicant: Taiwan Semiconductor Manufacturing Co., Ltd., Hsinchu (TW)

(72) Inventors: Ya-Ting TSAI, Hsinchu (TW); Ming-Shiuan SHE, Hsinchu (TW); Gin-Chen HUANG, Hsinchu (TW)

(73) Assignee: Taiwan Semiconductor Manufacturing Co., Ltd., Hsinchu (TW)

(21) Appl. No.: 18/972,496

(22) Filed: Dec. 6, 2024

(51) Int. Cl. H10D 84/01; H10D 64/01; H10D 84/83

(52) U.S. Cl. CPC H10D 84/0151; H10D 64/017; H10D 84/832

(57) ABSTRACT

A method for forming an integrated circuit includes forming a plurality of semiconductor fins and trench isolation regions between the semiconductor fins. The method includes forming a first dielectric layer on top and side surfaces of the semiconductor fins and on a top surface of the trench isolation regions. The method includes forming a second dielectric layer on the first dielectric layer and removing the second dielectric layer from a top surface of the first dielectric layer by performing a chemical mechanical planarization (CMP) process on the second dielectric layer. The second dielectric layer is removed in multiple subsequent etching processes. Formation of the source/drain regions in the fins is then performed.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-15 are cross-sectional and top views of an integrated circuit at various stages of processing, in accordance with some embodiments.

FIG. 16 is a flow diagram of a method of manufacturing an integrated circuit, in accordance with some embodiments.

FIG. 17 is a flow diagram of a method of manufacturing an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets).

Embodiments of the disclosure provide a method for forming nanostructure transistors with reduced damage to the top nanostructure/channel of the transistors regardless of the local density of the semiconductor fins (OD) from which the transistors are formed. After formation of shallow trench isolation regions between fins, a process is performed to form dielectric barrier structures on the shallow trench isolation regions to protect the shallow trench isolation regions during subsequent processing steps. The process for forming the dielectric barrier structures includes depositing a dielectric layer on the shallow trench isolation regions and on the sidewalls and top surfaces of the semiconductor fins, and depositing a bottom antireflective coating (BARC) layer on the dielectric layer.

Embodiments of the present disclosure utilize a multistep etching process to remove the BARC layer and the dielectric layer from the tops of all fins without damaging the top layer of the fins, regardless of the local density of the fins. The multistep etching process includes performing a chemical mechanical planarization (CMP) on the BARC layer, followed by an etchback process that reduces the height of the BARC layer relative to the dielectric layer, and concluding with an etching process that removes the dielectric layer from the top of the fins. This results in transistors that have top channels without substantial damage, regardless of the local density of fins. This maintains a desired effective width of the top channels of the transistors, resulting in superior electrical characteristics, and better overall performance. Furthermore, this can improve wafer yields and overall function of integrated circuits and electronic devices in which the integrated circuits are embedded.

While the figures and description focus primarily on examples in which the transistors are nanostructure transistors including stacks of channels, principles of the present disclosure extend to other types of transistors. Principles of the present disclosure extend to MOS transistors, FinFET transistors and other types of transistors.

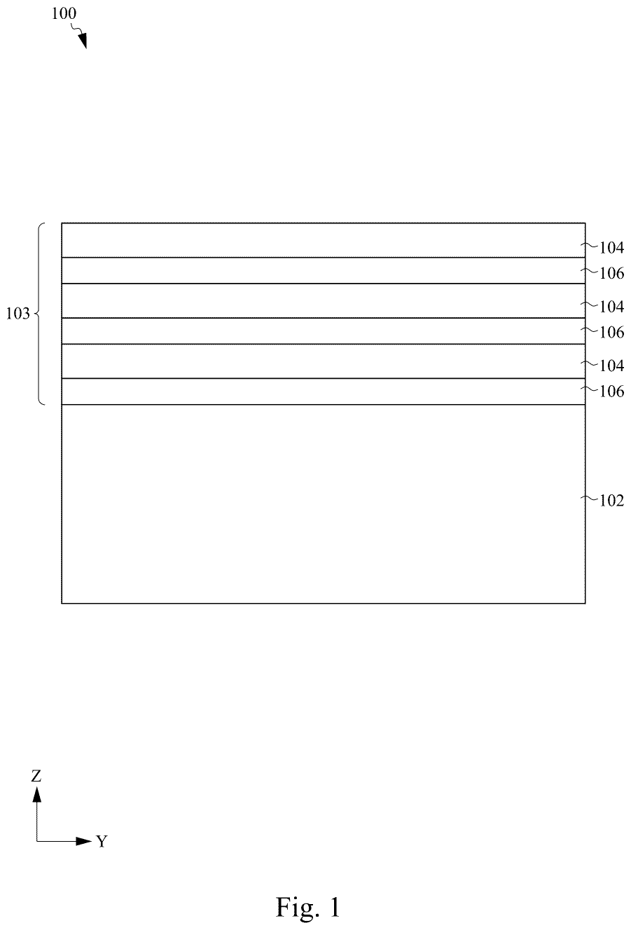

FIGS. 1-15 are cross-sectional views of an integrated circuit 100 fabricated in accordance with some embodiments of the present disclosure. The fabrication process results in a plurality of transistors 101, as will be described in further detail below.

FIG. 1 is a cross-sectional view of the integrated circuit 100 at an intermediate stage of processing. The integrated circuit 100 includes a substrate 102. The substrate 102 may be a semiconductor substrate, such as a bulk semiconductor, or the like, which may be doped (e.g., with a P-type or an N-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and sacrificial semiconductor layers 106 alternating with each other. In the example of FIG. 1 the stack 103 includes three and three sacrificial semiconductor layers 106. However, in practice, different numbers of semiconductor layers 104 and sacrificial semiconductor layers 106 can be utilized without departing from the scope of the present disclosure.

As will be set forth in further detail below, the semiconductor layers 104 will be patterned to form stacked channels of a plurality of transistors. As set forth in more detail below, the sacrificial semiconductor layers 106 will eventually be entirely removed and are utilized to enable forming gate metals and other structures around the semiconductor nanostructures. In

In some embodiments, the semiconductor layers 104 may be formed of a first semiconductor material suitable, such as silicon, silicon carbide, or the like, and the sacrificial semiconductor layers 106 may be formed of a second semiconductor material, such as silicon germanium or the like. Each of the layers of the multi-layer stack 103 may be epitaxially grown using a process such as chemical vapor deposition (CVD), atomic layer deposition (ALD), vapor phase epitaxy (VPE), molecular beam epitaxy (MBE), or the like.

Due to high etch selectivity between the materials of the semiconductor layers 104 and the sacrificial semiconductor layers 106, the sacrificial semiconductor layers 106 of the second semiconductor material may be removed without significantly etching the semiconductor layers 104 of the first semiconductor material, thereby allowing the semiconductor layers 104 to be released to form stacked channel regions of transistors, as will be set forth in more detail below.

In one example, the semiconductor layers 104 are silicon and the sacrificial semiconductor layers 106 are silicon germanium. In some embodiments, the sacrificial semiconductor layers 106 have a concentration of germanium between 10% and 50%, though other concentrations can be utilized without departing from the scope of the present disclosure. This enables the sacrificial semiconductor layers 106 to be selectively etchable with respect to the semiconductor layers 104. Other materials and concentrations can be utilized without departing from the scope of the present disclosure.

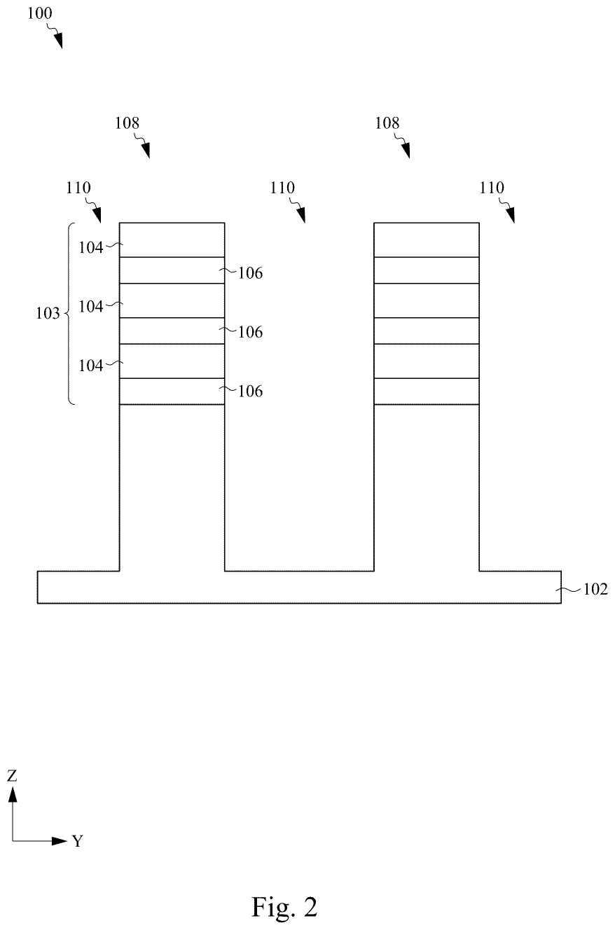

In FIG. 2, a plurality of semiconductor fins 108 have been formed from the stack 103. The semiconductor fins 108 are formed by forming trenches 110 in the stack 103 and in the substrate 102. Though not shown in FIG. 1, a hard mask layer is first formed and patterned on the stack 103. The trenches 110 can be formed with an anisotropic etching process that etches in the downward direction in the presence of the patterned hard mask. The etching process defines semiconductor fins 108 by forming trenches 110 through the sacrificial semiconductor layers 106, the semiconductor layers 104, and the substrate 102.

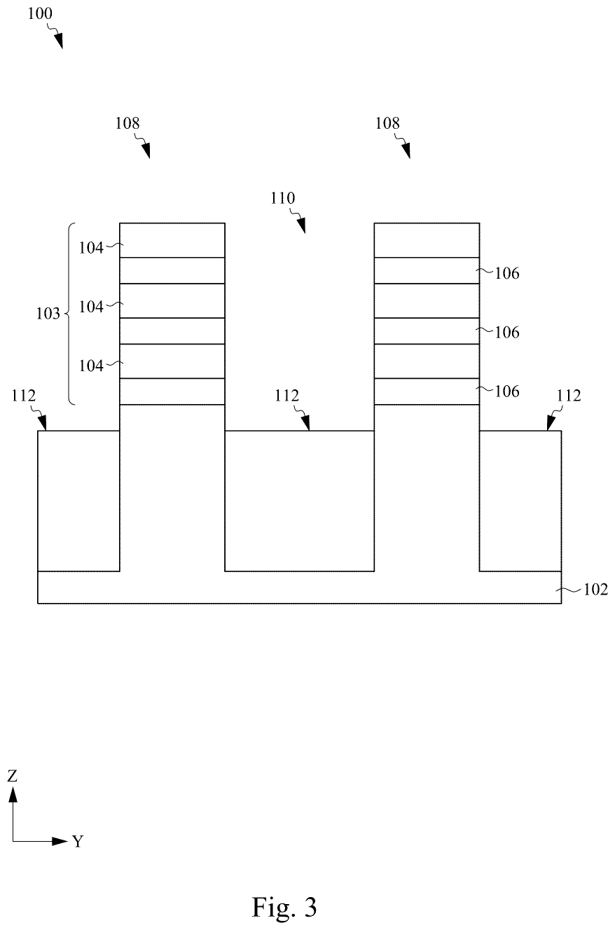

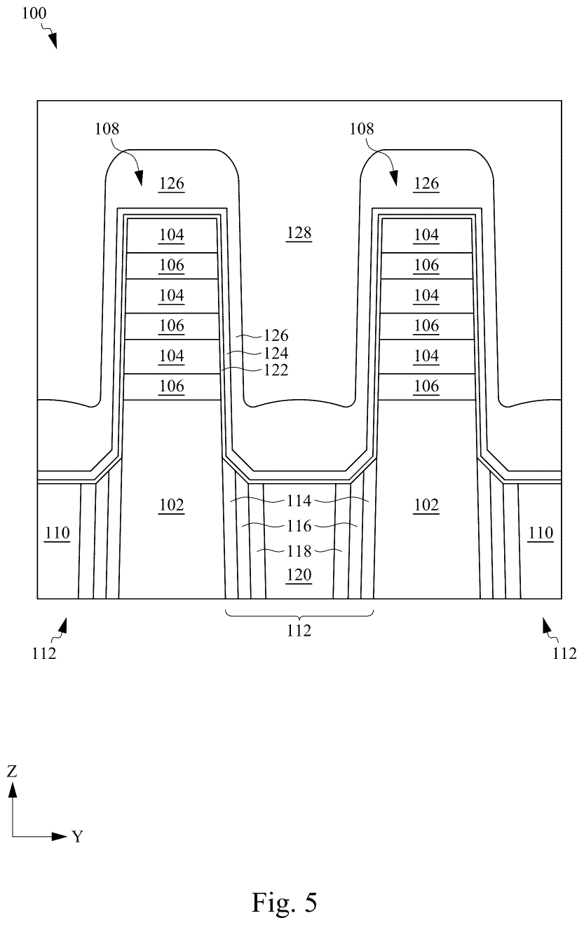

In FIG. 3, shallow trench isolation regions 112 have been formed by depositing a dielectric material in the trenches 110 between fins 108. FIG. 3 illustrates the shallow trench isolation regions 112 as a single layer material. However, in practice, a plurality of layers, as will be set forth in further detail in FIG. 5. The dielectric layer may be deposited by chemical vapor deposition (CVD), atomic layer deposition (ALD), physical vapor deposition (PVD), or other suitable deposition processes. In an exemplary embodiment, the dielectric material includes silicon oxide. However, the dielectric material can include SiN, SiCN, SiOC, SiOCN, or other dielectric materials without departing from the scope of the present disclosure.

After deposition of the dielectric material of the trench isolation region 112, an etch-back process has been performed to recess the top of the shallow trench isolation regions 112 below the lowest sacrificial semiconductor layers 106. This results in the shallow trench isolation regions 112 having a top surface that is lower than the bottom surface of the lowest sacrificial semiconductor layer 106 of each fin. Other processes can be utilized to form the shallow trench isolation regions 112 without departing from the scope of the present disclosure.

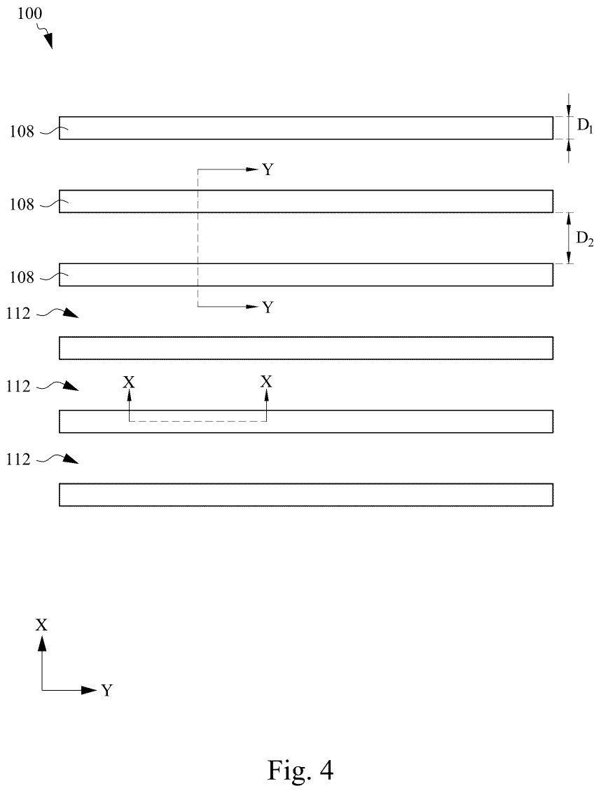

FIG. 4 is a top view of the integrated circuit one hundred at the stage of processing shown in FIG. 3. FIG. 4 illustrates the region of the integrated circuit one hundred in which a plurality of semiconductor fins 108 have been formed. The semiconductor fins extend in the X direction. The shallow trench isolation regions 112 are formed between adjacent fins 108 and extend in the X direction.

The semiconductor fins have a width dimension D1 in the Y direction the shallow trench isolation regions 112 have a width dimension D2 in the Y direction. The area of the fins 108 may also be termed OD area. The density of the fins 108 in a particular area can be calculated as D1/(D1+D2). In some embodiments, D1 is between 15 nm and 25 nm. In some embodiments, D2 is between 40 nm and 50 nm. Other dimensions can be utilized without departing from the scope of the present disclosure.

FIG. 4 illustrates a single area of the integrated circuit one hundred having a particular density of fins 108 (or OD density). However, in practice, the integrated circuit one hundred can have multiple areas of fins 108 having differing fin densities. For example, a single integrated circuit may have logic transistors, I/O transistors, electrostatic discharge (ESD) protection transistors, or other types of transistors. Each of these types of transistors may be formed from fins 108 having different widths in the Y direction, as well as different widths of shallow trench isolation regions.

As will be set forth in more detail below, due to the differing fin densities, it is possible that process steps can result in different types of damage or problems in the various different areas of different fin densities. Embodiments of the present disclosure provide to reduce or entirely prevent the various types of damage in all the different fin density areas.

FIG. 4 also illustrates cut lines Y and cut lines X. The cut lines Y indicate the location at which the cross-section is taken for the various “Y-view” figures in which the horizontal axis of the figure is the Y direction. The cut lines X indicate the location at which the cross-section is taken for the various “X-view” figures in which the horizontal axis of the figure is the X direction.

FIG. 5 is a Y-view of the integrated circuit one hundred, in accordance with one embodiment. FIG. 5 illustrates the formation of layers from which dielectric barrier structures will be formed to cover the shallow trench isolation regions 112.

FIG. 5 also illustrates an example in which the shallow trench isolation regions 112 include a plurality of layers. In particular, the shallow trench isolation regions 112 include a first liner layer 114. The first liner layer 114 is in direct contact with the sidewalls of the substrate 102 in the trenches 110 and on the bottom of the trenches 110 (not shown in FIG. 5). The dielectric liner layer 114 can include SiO, SiN, SION, SiCN, SiOC, SiOCN, or other suitable dielectric materials. In a particular example given herein, the dielectric liner layer 114 includes silicon oxide. The dielectric liner layer 114 can be deposited by CVD, ALD, PVD, or other suitable dielectric processes.

The shallow trench isolation regions 112 include a second liner layer 116. The second liner layer 116 is in direct contact with first liner layer 114. The dielectric liner layer 116 can include SiO, SiN, SION, SiCN, SiOC, SiOCN, or other suitable dielectric materials. The dielectric liner layer 116 can be deposited by CVD, ALD, PVD, or other suitable dielectric processes.

The shallow trench isolation regions 112 include a third dielectric liner layer 118. The liner layer 118 is in direct contact with liner layer 116. The dielectric liner layer 118 can include SiO, SiN, SION, SiCN, SiOC, SiOCN, or other suitable dielectric materials. The dielectric liner layer 118 can be deposited by CVD, ALD, PVD, or other suitable dielectric processes.

The shallow trench isolation regions 112 include a shallow trench isolation layer 120. The shallow trench isolation layer 120 corresponds to a primary layer of the shallow trench isolation region 112. In some conceptions, the shallow trench isolation layer 120 may the shallow trench isolation layer 120 can include SiO, SiN, SION, SiCN, SiOC, SiOCN, or other suitable dielectric materials. In one particular example, the shallow trench isolation layer 120 includes silicon oxide. The shallow trench isolation layer 120 can be deposited by CVD, ALD, PVD, or other suitable dielectric processes.

In FIG. 5, a thin semiconductor layer 122 has been deposited on side and top surfaces of the semiconductor fins 108, and on the top surfaces of the shallow trench isolation regions 112. The thin semiconductor layer 122 is in direct contact with the semiconductor layers 104, the sacrificial semiconductor layers 106, and the dielectric layers 114, 116, 118, and 120 of the shallow trench isolation regions 112. The semiconductor layer 122 can include silicon, silicon germanium, or other suitable semiconductor materials. In one example, the semiconductor layer 122 is a same material as the substrate 102 and the semiconductor layers 104. The semiconductor layer 122 can be formed by CVD, ALD, PVD, epitaxial growth, or other suitable deposition processes.

In FIG. 5, a dielectric liner layer 124 has been deposited on the semiconductor layer 122. The dielectric liner layer 124 lines the top and side surfaces of the semiconductor fins 108, and the top surfaces of the shallow trench isolation regions 112, with the semiconductor layer 122 positioned between the dielectric layer 124 and the dielectric fins 108 and the shallow trench isolation regions 112. The dielectric liner layer 124 can include SiO, SiN, SiON, SiCN, SiOC, SiOCN, or other suitable dielectric materials. In particular example, the dielectric liner layer 124 includes silicon oxide. The dielectric liner layer 124 can be formed by CVD, ALD, PVD, or other suitable dielectric processes.

In FIG. 5, a dielectric layer 126 has been deposited on the top and side surfaces of the semiconductor fins 108 and on the top surface of the shallow trench isolation regions 112. The dielectric layer 126 is in direct contact with the dielectric liner layer 124. The dielectric layer 126 can include SiO, SiN, SION, SiCN, SiOC, SiOCN, or other suitable dielectric materials. In a particular example, the dielectric layer 126 include silicon nitride. The dielectric layer 126 can be formed by CVD, ALD, PVD, or other suitable deposition processes.

As will be described in further detail below, the dielectric layer 126 is a primary layer of a dielectric barrier structure that protects the trench isolation regions 112 in subsequent processing steps. To form the dielectric barrier structures, the dielectric layer 126 will be removed from the tops of the fins 108 and from upper side surfaces of the fins 108. However, it is possible that the removing the dielectric layer 126 from the top surfaces of the fins 108 can result in the various problems in the various regions of different fin density of the integrated circuit one hundred. In particular, it is possible that a portion of the dielectric layer 126 can remain on the top surfaces of the fins 108 in areas of high fin density. Furthermore, it is possible that the top semiconductor layer 104 may be damaged or reduced in width in layers of lower fin density. However, as will be set forth in more detail below, embodiments of the present disclosure avoid these problems and remove the dielectric layer 126 from the tops of the fins 108 in all of the various density areas without damaging the top semiconductor layer 104 in any of the various areas of different fin density.

In FIG. 5, a dielectric layer 128 has been formed on the dielectric layer 126. In some embodiments, the dielectric layer 128 is a BARC layer including an organic polymer or other type of dielectric layer. The dielectric layer 128 fills the remaining space between the semiconductor fins 108. The dielectric layer 128 extends significantly higher than the top surface of the dielectric layer 126. While FIG. 5 illustrates only a single area of the integrated circuit one hundred having a particular fin density, unless otherwise specified, the processes and structures formed in one area are also formed at other areas having differing fin densities. The dielectric layer 128 can also include SiO, SiN, SION, SiCN, SiOC, SiOCN, or other suitable dielectric materials.

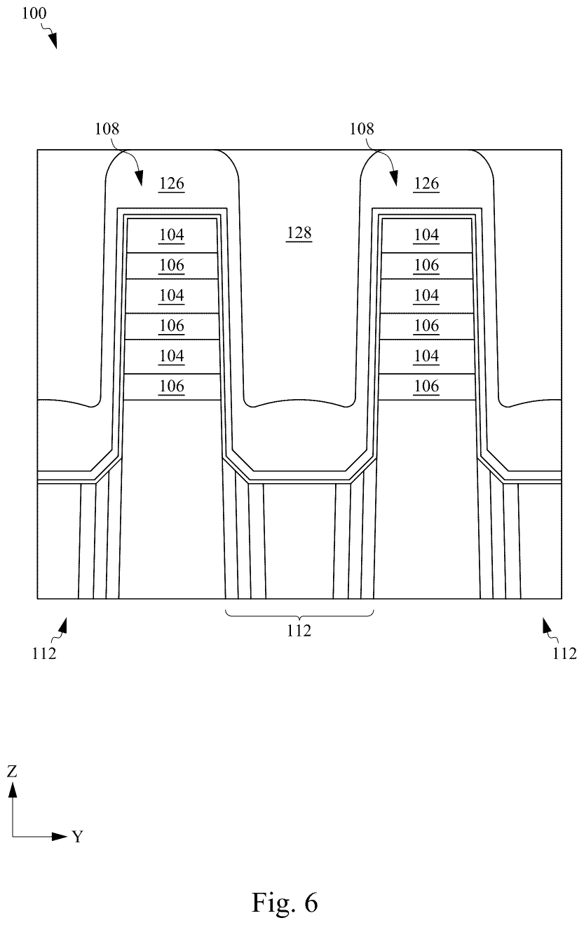

In FIG. 6, a CMP processes been performed, in accordance with some embodiments. The CMP process reduces the height of the dielectric layer 128. In particular, the CMP process the dielectric layer 128 has a top surface that is coplanar with a top surface of the dielectric layer 126. In some embodiments, the dielectric layer 126 is not etched by the CMP process, the access an etch stop layer for the CMP process. In some embodiments, the dielectric layer 126 is partially etched by the CMP process.

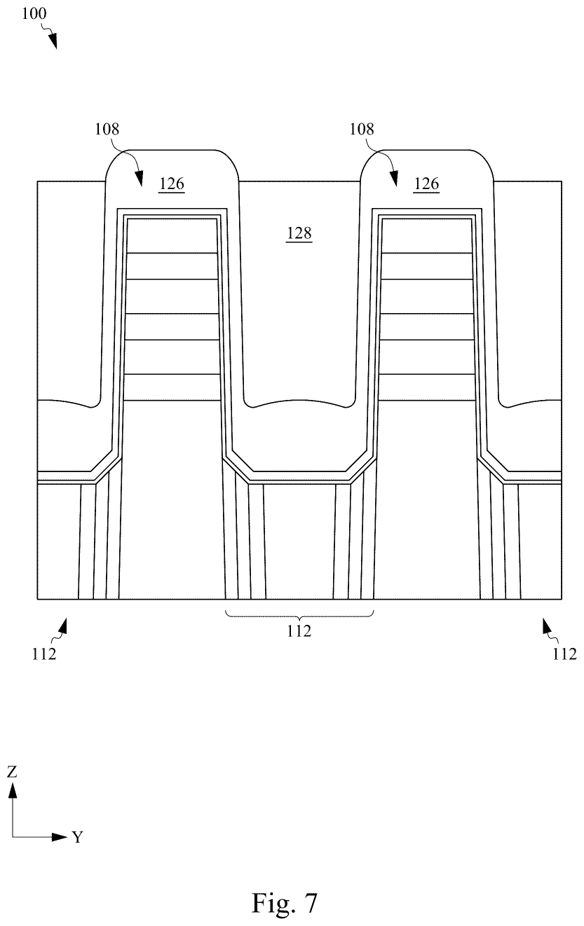

In FIG. 7, an etchback process has been performed, in accordance with some embodiments. The etchback process reduces the height of the top surface of the dielectric layer 128 without substantially reducing the height of the dielectric layer 126. Accordingly, the etching process utilized for the etchback selectively etches the material of the dielectric layer 128 with respect to the material of the dielectric layer 126. The etchback process can include a dry etch process, or other suitable etching processes. The etching process can include a timed etch that etches the dielectric layer 128 to a selected height.

In some embodiments, after the etchback process, the top surface of the BARC layer 128 is higher than a top surface of the fins 108 and lower than a top surface of the dielectric layer 126. In some embodiments, the top surface of the dielectric layer 128 is lower than a top surface of the fins 108 after the etchback process.

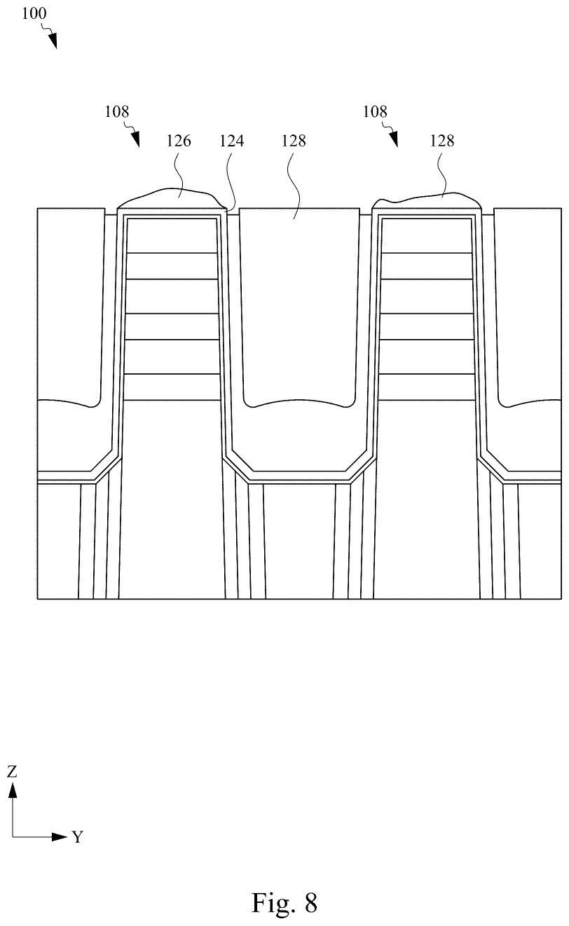

In FIG. 8, an etching process has been performed to at least partially remove the portion of the dielectric layer 126 on top of the fins 108. The etching process can also partially etch the BARC layer 128. The etching process can include a wet etch, a dry etch, a timed etch, or other etching processes. The etching process may selectively etch the dielectric layer 126 with respect to the material of the BARC layer 128. At the stage of processing shown in FIG. 8, the top surfaces of the dielectric layer 126 and BARC layer 128 are uneven, in some embodiments. In some embodiments, the etchback process is a dry etching process using an etching gas that selectively etches the dielectric layer 126 with respect to the BARC layer 128.

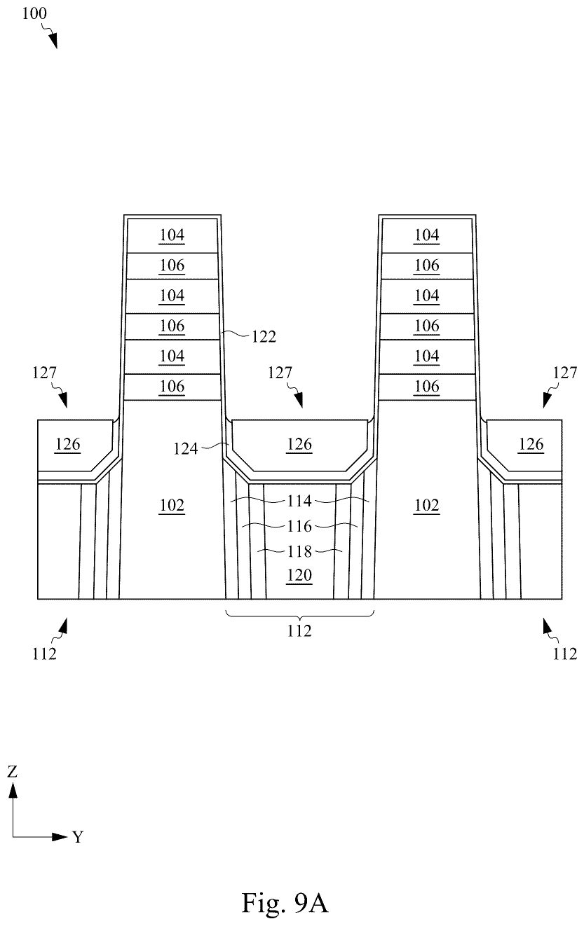

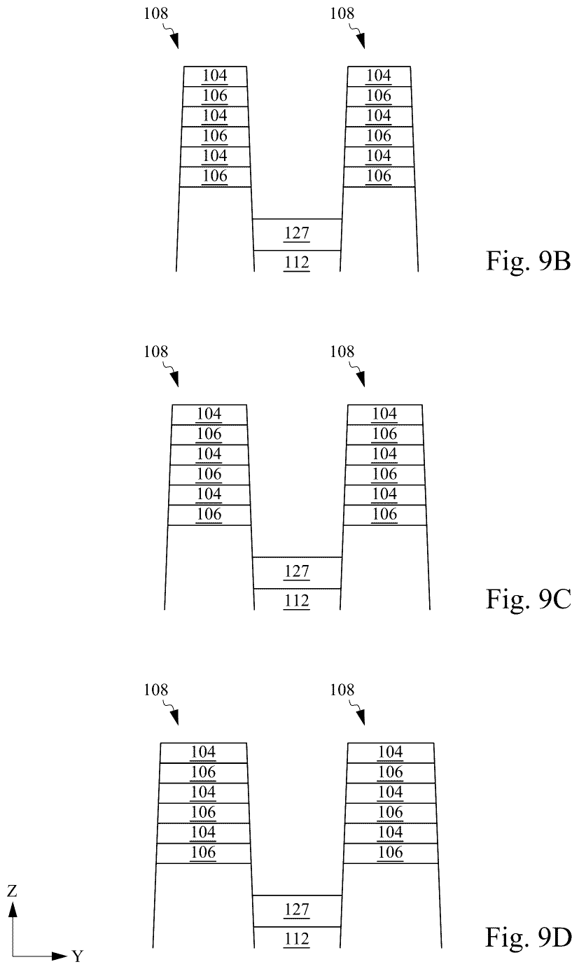

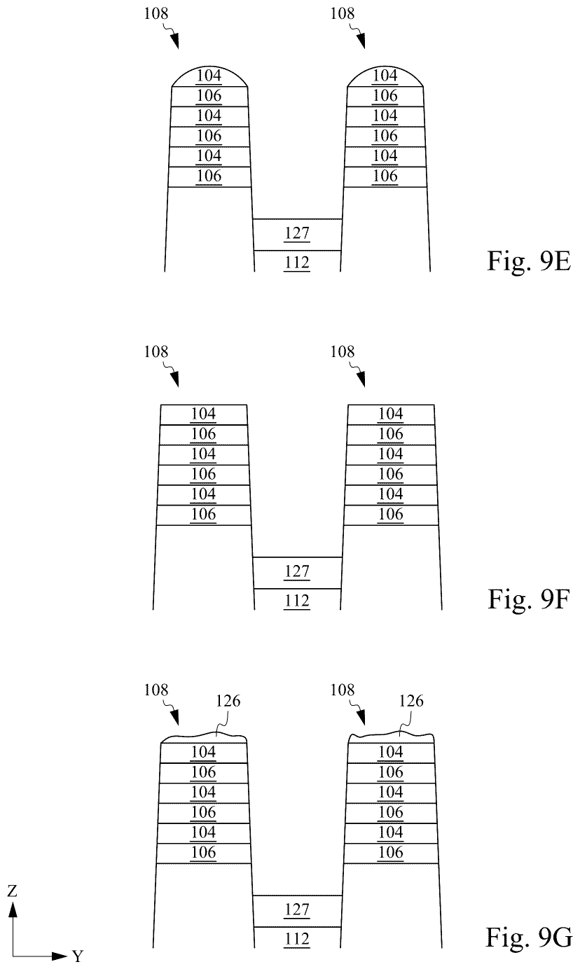

In FIG. 9A, an etching process has been performed to completely remove the BARC layer 128 and to remove the dielectric layer 126 completely from the top surfaces of the semiconductor fins 108 and from the upper sidewalls of the fins 108. The etching process also removes the dielectric layer 124 from the top surfaces of the semiconductor fins 108 and from the upper sidewalls of the fins 108. The etching process can include a wet etch, a dry etch, a timed etch, or other suitable etching processes. In some embodiments, the etchback process is a dry etching process using an etching gas that selectively etches the dielectric layer 126 and the BARC layer 128 with respect to other materials present.

In some embodiments, the top surface of the dielectric layer 126 is substantially even with a top surface of the dielectric layer 124 after the etching process shown in FIG. 9A. In FIG. 9A, the top surface of the dielectric layer 126 is lower than a bottom surface of the lowest sacrificial semiconductor nanostructures 106.

At the stage of processing shown in FIG. 9, dielectric barrier structures 127 have been formed on the shallow trench isolation regions 126. The dielectric barrier structures 127 include the dielectric layer 124 and the dielectric layer 126. The dielectric layer 126 is a primary layer of the dielectric barrier structure 127.

The dielectric barrier structure 127 protects the shallow trench isolation regions 112 during subsequent etching processes. For example, eventually the sacrificial semiconductor layers 106 will be replaced with sacrificial dielectric nanostructures. The sacrificial dielectric nanostructures have a same material as the trench isolation layer 120, in some embodiments. Eventually, the sacrificial dielectric nanostructures will be removed and replaced with gate metals. The process that removes the sacrificial dielectric nanostructures can significantly damage or remove the shallow trench isolation layer 120, thereby adversely affecting the function of the shallow trench isolation regions 112. However, with the dielectric barrier structures 127 present, the sacrificial dielectric nanostructures can be removed without significantly damaging the shallow trench isolation regions 112. Alternatively, the dielectric barrier structures 127 can protect the shallow trench isolation regions 112 during other processing steps. In some embodiments, the dielectric barrier structures 127 remain after formation of the transistors is complete. In some embodiments, the dielectric barrier structures 127 may be removed in a subsequent processing step.

FIGS. 9B, 9C, and 9D illustrate areas of low fin density, medium fin density, and high fin density, respectively, for the integrated circuit one hundred that has undergone the etching steps described in relation to FIGS. 6-9A, in accordance with some embodiments. In one example, the fin density in FIG. 9B is between 20% and 30%, the fin density in FIG. 9C is between 30% and 40%, and the fin density in FIG. 9D is between 40% and 60%, though other fin densities can be utilized without departing from the scope of the present disclosure. FIGS. 9B-9D illustrate that in each of the various fin density regions, the dielectric layer 126 has been completely remove of the fins 108 without damaging the top semiconductor layer 104. In some embodiments, the sidewalls of the top semiconductor layer 104 in each of the regions is between 85° and 90°. In some embodiments, the thickness of the dielectric barrier structure 127 is between 20 nm and 60 nm in each of the regions. The angle of the sidewalls of the semiconductor layers 104 is initially defined in formation of the fins. Principles of the present disclosure help ensure that the angle of the top semiconductor layer 104 is not reduced during processing steps subsequent to the initial definition of the fins.

In some embodiments, the fin concentration can be expressed as a ratio of the width of a semiconductor fin of the to the width of a trench isolation region of the region. In this way, regions that have different fin concentrations all have top semiconductor layers to sidewalls make a substantially same angle relative to vertical.

FIGS. 9E-9G illustrate areas of low fin density, medium fin density, and high fin density in integrated circuit in which the etching process of FIGS. 6-9A has not been utilized for removal of the dielectric layer 126 from the tops of the fins 108. As can be seen in FIG. 9E, at the low fin density region the top semiconductor layer 104 has been significantly damaged. The sidewalls of the top semiconductor layer 104 in FIG. 9 the make a low angle and, accordingly, much of the top layer is relatively narrow in the Y direction. The top semiconductor layer 104 is eventually separated into the top channels of a plurality of transistors, as will be set forth in more detail below. The width of the top channels in the Y direction, which corresponds to the channel width, is effectively reduced. This results in an overall lower conductivity of the top channels in saturation mode. Accordingly, the electrical performance of transistors formed from the fins 108 of FIG. 9E is reduced.

In FIG. 9G, at the high fin density region, a portion of the dielectric layer 126 still remains on top of the fins 108. This can be highly damaging to the formation of transistors from these fins. In some cases, the transistors may be completely nonfunctioning if source/drain trenches are not properly formed due to the presence of the dielectric layer 126 on the top of the fins 108. Only in the region 9F is the dielectric layer 126 completely removed without damaging the top semiconductor layer 104. Accordingly, the semiconductor fins 108 of FIGS. 9B-9D, processed in accordance with principles of the present disclosure, are each properly formed and will result in properly functioning transistors.

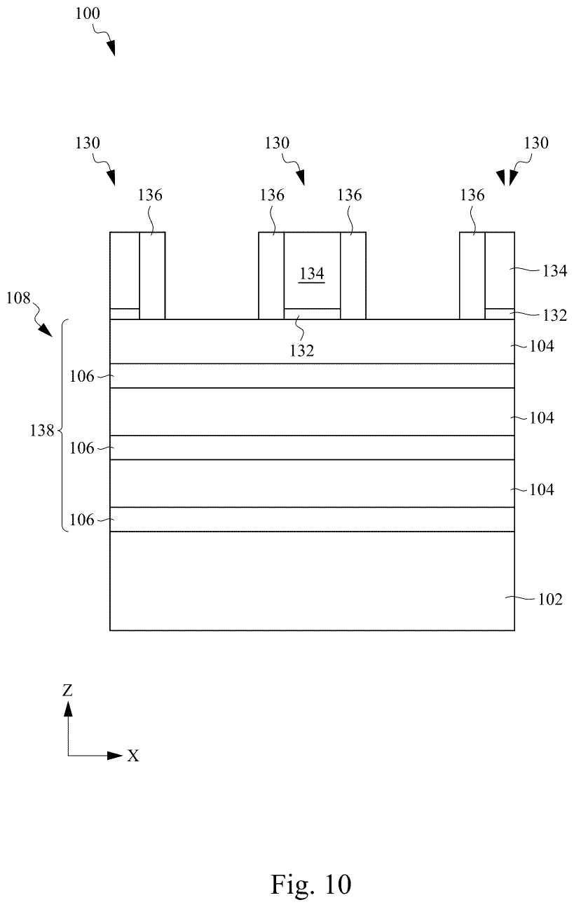

FIG. 10 is an X-view of the integrated circuit 100, in accordance with some embodiments. In FIG. 10, sacrificial gate structures 130 have been formed over the fins 108. With reference to FIG. 4, a plurality of sacrificial gate structures each extend parallel to each other over the fins 108 and the shallow trench isolation regions 112.

The sacrificial gate structures 130 include a dielectric layer 132. In an exemplary embodiment, the dielectric layer 132 includes silicon oxide. However, alternatively, the dielectric layer 132 can include SiN, SiCN, SiOC, SiOCN, or other dielectric materials without departing from the scope of the present disclosure. In some embodiments, the dielectric layer 132 has a low-K dielectric material. The dielectric layer 132 can be deposited by CVD, ALD, or PVD.

The sacrificial gate structures include a sacrificial gate layer 134 on the dielectric layer 132. The sacrificial gate layer 134 can include materials that have a high etch selectivity with respect to the trench isolation regions 112. In an exemplary embodiment, sacrificial gate layer 134 includes polysilicon. However, the sacrificial gate layer 134 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 134 may be deposited by physical vapor deposition (PVD), CVD, sputter deposition, or other techniques for depositing the selected material. Though not shown in FIG. 4, in some embodiments, the sacrificial gate structures 130 may include additional dielectric layers above the sacrificial gate layer 134.

In FIG. 10, gate spacer layer 136 has been formed on the sidewalls of the sacrificial gate structures 130. In particular, the gate spacer layer 136 may be formed on sidewalls of the dielectric layer 132 and the sacrificial gate layer 134. The gate spacer layer 136 may also be formed on other exposed surfaces of the integrated circuit. The gate spacer layer 136 can be formed by PVD, CVD, ALD, or other suitable deposition processes. Following formation of the gate spacer layer 136, horizontal portions (e.g., in the X-Y plane) of the gate spacer layer 136 may be removed by an anisotropic etching process, thereby exposing upper surfaces of the fins 108. After patterning of the gate spacer layers, vertically thicker portions of the gate spacer layer 136 may remain. The gate spacer layer 136 can include one or more of SiO, SiN, SION, SiCN, SiOCN, SiOC, or other suitable dielectric materials. Though not shown in FIG. 4, in some embodiments an additional gate spacer layer or liner layer is also formed on the gate spacer layer 136. The additional gate spacer layer can include one or more of SiO, SiN, SiON, SiCN, SiOCN, SiOC, or other suitable dielectric materials.

In FIG. 1, source/drain trenches 131 have been formed, in accordance with some embodiments. After patterning of the gate spacer layer 136, one or more etching processes are performed to form source/drain trenches 131 in the fins 108. Forming the source/drain trenches 131 includes etching through each of the semiconductor layers 104, each of the sacrificial semiconductor layers 106, and a portion of the substrate 102. Accordingly, the removal operations may include suitable etch operations for removing materials of the semiconductor layers 104, the sacrificial semiconductor layers 106, and the substrate 102. The etching processes can include reactive ion etching (RIE), neutral beam etching (NBE), atomic layer etching (ALE), or the like.

Formation of the source/drain trenches 131 results in formation of stacks 138 of channels 105. In particular, the remaining portions of the semiconductor layers 104 after formation of the source/drain trenches 131 now correspond to stacked channels 105 of a transistor. Formation of the source/drain trenches 131 results in formation of a plurality of sacrificial semiconductor nanostructures 107 from the sacrificial semiconductor layers 106.

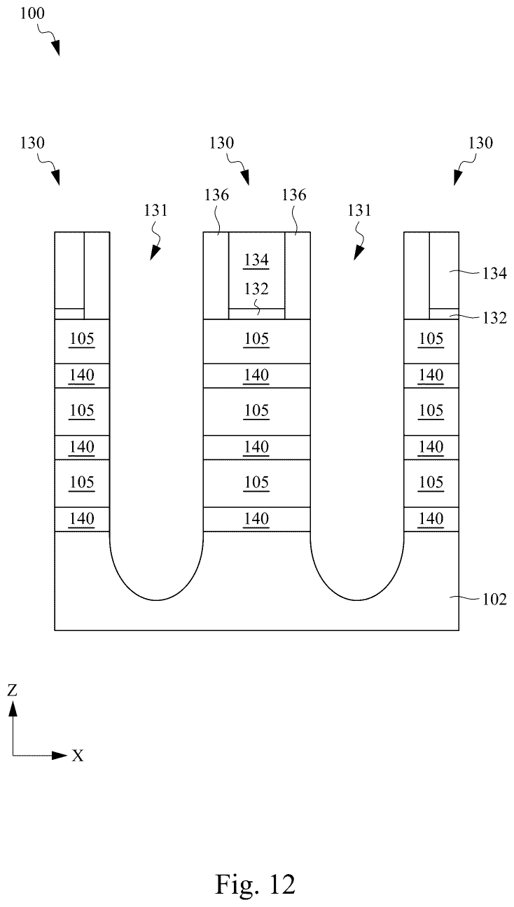

In FIG. 12, an etching process has been performed, in accordance with some embodiments. The etching process completely removes the sacrificial semiconductor nanostructures 107. Accordingly, the etching process can utilize an etchant that selectively etches the material of the sacrificial semiconductor nanostructures 107 relative to other exposed materials, including the material of the substrate 102 and the channels 105.

In FIG. 12, sacrificial dielectric nanostructures 140 have been formed in place of the sacrificial semiconductor nanostructures 107, in accordance with some embodiments. The sacrificial dielectric nanostructures 140 are formed by depositing a dielectric material in the trenches 131 and in the gaps formed between the channels 105 by removal of the sacrificial semiconductor nanostructures 107. The dielectric material can be deposited by CVD, ALD, or other suitable deposition processes. The dielectric material can include SiO, SiN, SION, SiCN, SiOC, SiOCN, or other suitable dielectric materials. In a particular example, the dielectric material is a same material as the shallow trench isolation layer 120.

After deposition of the dielectric material, an anisotropic etching process is performed to remove the dielectric material from the trenches 130 one. The sacrificial gate structures 130, including the gate spacer layers 136, acts as a mask during the etching process. The dielectric material is removed from all locations not directly below the sacrificial gate structures 130 and the gate spacer layers 136. The etching process results in formation of the sacrificial dielectric nanostructures 140 from the dielectric material. The sacrificial dielectric nanostructures 140 may also be termed dielectric oxide interposers, in accordance with some embodiments.

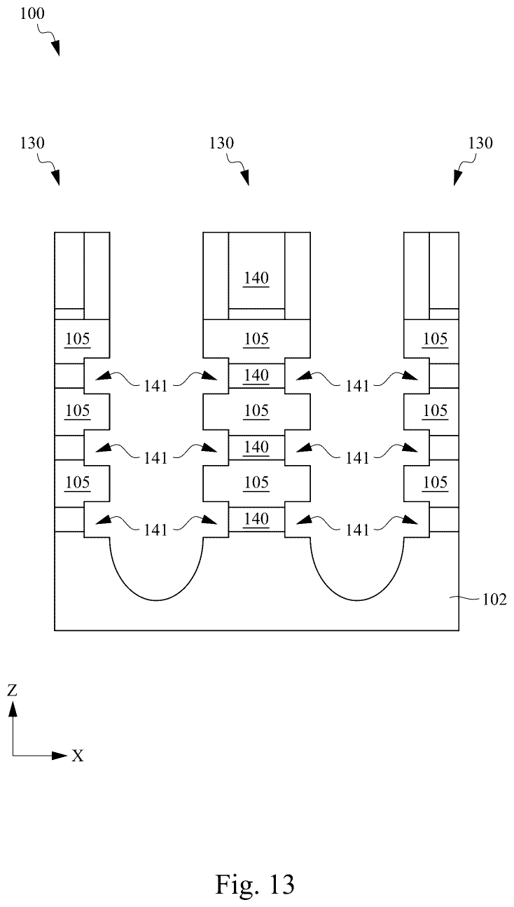

In FIG. 13, a selective etching process is performed to recess exposed end portions of the sacrificial dielectric nanostructures 140 without substantially etching the channels 105. More particularly, recesses 141 are formed in the sacrificial dielectric nanostructures 140 adjacent channels 105, or between the lowest channel 105 and the substrate 102. The recesses 141 can be formed by performing an etching process that selectively etches the material of the sacrificial dielectric nanostructures 140 with respect to the material of the channels 105 and the substrate 102.

While the trench isolation regions 112 in the present in the view of FIG. 13, the trench isolation regions 112 are protected during the etching process by the dielectric barrier structures 127. As described previously, in some embodiments, the shallow trench isolation layer 120 is a same material as the sacrificial dielectric nanostructures 140. Accordingly, if the dielectric barrier structures 127 are not present during the etching process, it is possible that the shallow trench isolation layer would also be etched.

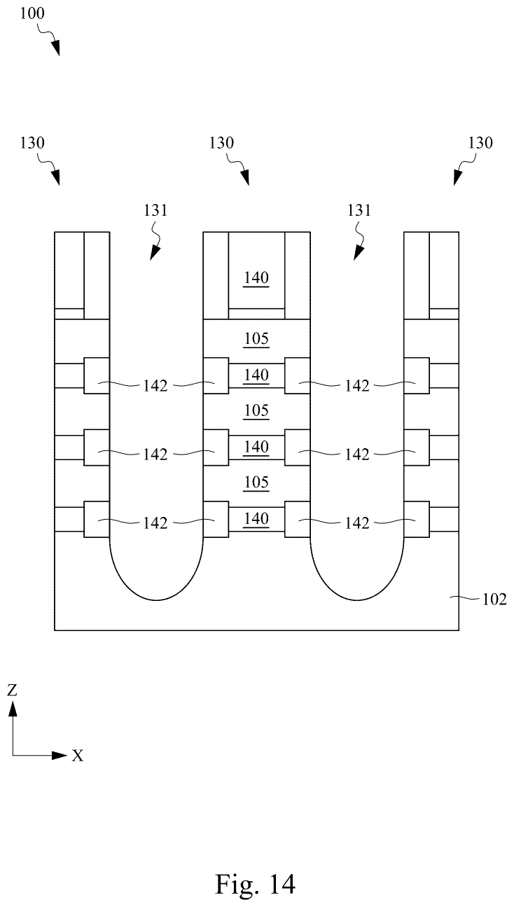

In FIG. 14, a dielectric layer has been deposited. The dielectric layer has been deposited in a conformal deposition process on exposed surfaces of the channels 105, the gate spacer layer 136, the sacrificial dielectric nanostructures 140, and the substrate 102. Most notably, the dielectric layer 132 fills the recesses 141. The dielectric layer 132 can include SiCN, SiOCN, SION, SiN, or other suitable dielectric materials. The dielectric layer can be formed by a suitable deposition method such as CVD, ALD, PVD, or other deposition processes.

In FIG. 14, inner spacers 142 have also been formed in the recesses 141. The inner spacers 142 are in contact with ends of the sacrificial semiconductor nanostructures 107 and with the channels 105. As will be set forth in further detail below, the inner spacers 142 separate gate metals from source/drain regions.

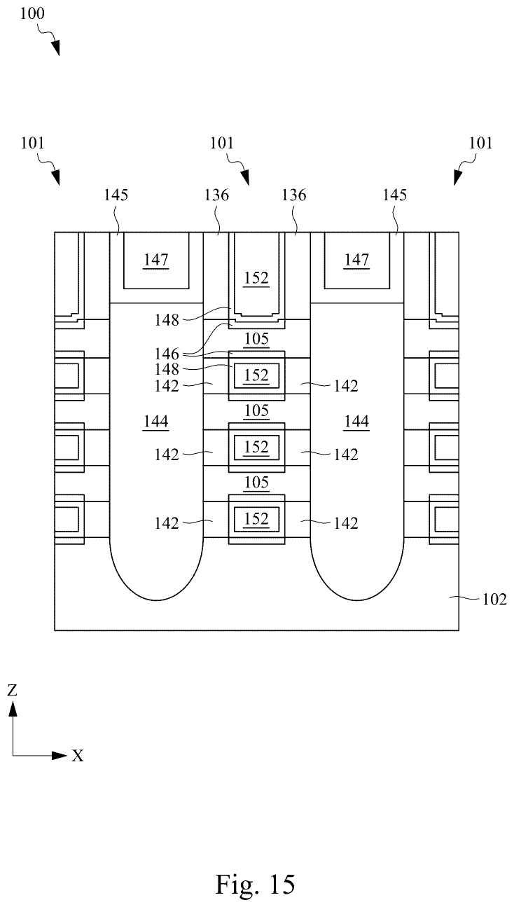

In FIG. 15, source/drain regions 144 have been formed in the source/drain trenches 131, in accordance with some embodiments. The source/drain regions 144 are epitaxially grown from the channels 105. The source/drain regions 144 are grown on exposed portions of the fins 108 and contact the channels 105. For each stack 138 of channels 105, there are two source/drain regions 144. Some stacks 138 of channels 105 may share a source/drain 138 with a stack 138 of channels 105 that is adjacent in the X direction.

The source/drain regions 144 may include any acceptable semiconductor material, such as appropriate for N-type or P-type devices. For N-type regions, the source/drain regions 144 include materials exerting a tensile strain in the channel regions, such as silicon, SiC, SiCP, SiP, or the like, in some embodiments. For P-type transistors, the source/drain regions 144 include materials exerting a compressive strain in the channel regions, such as SiGe, SiGeB, Ge, GeSn, or the like, in accordance with some embodiments. The source/drain regions 144 may have surfaces raised from respective surfaces of the fins and may have facets. Neighboring source/drain regions 144 may merge in some embodiments to form a singular source/drain region 144 over two neighboring fins 108.

In some embodiments, an in-situ doping process may be performed during formation of the source/drain regions 144 to implant to the source/drain regions 144 with N-type dopants or P-type dopants, depending on the conductivity type of the transistor or region being formed. The N-type dopants can include phosphorus, arsenic, antimony, or other suitable N-type dopants species. The P-type dopants can include boron, gallium, indium, or other suitable P-type dopants species. The source/drain regions 144 may be implanted with dopants followed by an annealing process. The source/drain regions 144 may have an impurity concentration of between about 10¹⁹ cm⁻³ and about 10²¹ cm⁻³.

In FIG. 15, a contact etch-stop layer (CESL) 145 and an interlevel dielectric (ILD) 142 have been formed, in accordance with some embodiments. The CESL layer 145 can include a thin dielectric layer conformally deposited on exposed surfaces of the source/drain regions 144, the gate spacer layers 124, and on other exposed surfaces. The CESL layer 145 can include SiN, SiC, SiOC, SIOCN, SiON, or other suitable dielectric materials. The CESL 145 can be deposited by CVD, ALD, PVD, or other suitable deposition processes.

The interlevel dielectric layer 147 covers the CESL layer 145. The interlevel dielectric layer 147 fills the remaining spaces between adjacent sacrificial gate structures 130. The interlevel dielectric layer 147 may correspond to a lowest interlevel dielectric layer of the integrated circuit 100. In some embodiments, the interlevel dielectric layer 147 may be termed ILD0. Though not shown herein, additional interlevel dielectric layers may be formed over the interlevel dielectric layer 147. A network of conductive vias and metal lines may be formed in the upper interlevel dielectric layers. The interlevel dielectric layer 147 can include SiO, SiON, SiN, SiC, SiOC, SIOCN, SiON, or other suitable dielectric materials. The interlevel dielectric layer 147 can be deposited by CVD, ALD, PVD, or other suitable deposition processes.

In some embodiments, a CMP process is performed after deposition of the interlevel dielectric layer 147. The result of the CMP process is that the top surfaces of the interlevel dielectric layer 147, the CESL layer 140, the gate spacer layer 136, and the sacrificial gate layer 134 are coplanar. The CMP process may also reduce the height of the sacrificial gate structures 130.

In FIG. 15, the sacrificial gate layer 134 has been removed, in accordance with some embodiments. The sacrificial gate layer 134 can be removed by an etching process that selectively etches the material of the sacrificial gate layer 134 with respect to adjacent materials, such as the dielectric layer 132 and the gate spacer layers 124. Removal of the sacrificial gate layer 134 results in gate trenches 144 between the gate spacer layers 124.

In FIG. 15, an etching process has been performed to remove the sacrificial dielectric nanostructures 140, in accordance with some embodiments. The sacrificial dielectric nanostructures 140 can be removed by a selective etching process using an etchant that is selective to the material of the channels 105, such that the sacrificial dielectric nanostructures 140 are removed without substantially etching the channels 105. In some embodiments, the etching process is an isotropic etching process using an etching gas, and optionally, a carrier gas, where the etching gas comprises F₂ and HF, and the carrier gas may be an inert gas such as Ar, He, N₂, combinations thereof, or the like. In some embodiments, the etching process results in a rounding of side surfaces of the channels 105. The etching process also results in gaps between the channels 105.

The trench isolation regions 112 are protected during removal of the sacrificial dielectric nanostructures 140 by the dielectric barrier structures 127. As described previously, in some embodiments, the shallow trench isolation layer 120 is a same material as the sacrificial dielectric nanostructures 140. Accordingly, if the dielectric barrier structures 127 are not present during the etching process, it is possible that the shallow trench isolation layer would also be etched.

In FIG. 15, a gate dielectric has been formed, in accordance with some embodiments. The gate dielectric includes an interfacial gate dielectric layer 146 and a high-K gate dielectric layer 148. The interfacial gate dielectric layer 146 has been deposited on exposed portions of the channels 105, in accordance with some embodiments. The interfacial gate dielectric layer 146 forms directly on the exposed portions of the channels 105. The high-K gate dielectric layer 148 forms on the interfacial gate dielectric layer 146 and on other exposed surfaces, such as the exposed sidewalls of the gate spacer layer 136, and the inner spacers 142.

The interfacial gate dielectric layer 146 is wrapped around the channels 105. The interfacial gate dielectric layer 146 can include a dielectric material such as silicon oxide, silicon nitride, or other suitable dielectric materials. The interfacial gate dielectric layer 146 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 146 can be formed by a thermal oxidation process, a chemical vapor deposition (CVD) process, or an atomic layer deposition (ALD) process. The interfacial gate dielectric layer 146 can have a thickness between 0.5 nm and 2 nm. Other materials, deposition processes, and thicknesses can be utilized for the interfacial gate dielectric layer 146 without departing from the scope of the present disclosure.

The high-K gate dielectric layer 148 is deposited in a conformal deposition process. The conformal deposition process deposits the high-K gate dielectric layer 148 on the interfacial gate dielectric layer 146, on the substrate 102, and on the gate spacer layer 136. The high-K gate dielectric layer 148 is wrapped around the channels 105. The high-K gate dielectric layer 148 has a thickness between 1 nm and 3 nm. The high-K dielectric layer includes one or more layers of a dielectric material, such as HfO₂, HfSiO, HfSION, HfTaO, HfTIO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K gate dielectric layer 148 may be formed by CVD, ALD, or any suitable method. Other thicknesses, deposition processes, and materials can be utilized for the high-K gate dielectric layer 148 without departing from the scope of the present disclosure.

In FIG. 15, a gate metal 152 has been deposited, in accordance with some embodiments. The gate metal 152 is deposited in place of the sacrificial gate layer 134 and the sacrificial dielectric nanostructures 140. Accordingly, the gate metal 152 is positioned in the gate trench above the hard mask layer 134 and the above the hard mask layer 150. The gate metal 152 is also wrapped around the channels 105.

In FIG. 15, a single gate metal 152 is illustrated as a gate electrode of a transistor 101. However, in practice, the gate metal 152 can include multiple gate metals. For example, the gate metal 152 can include one or more liner layers, one or more work function layers, and a gate fill material that fills the remaining spaces between the gate spacer layers 136. The gate metal 152 can include one or more of Ti, TiN, Ta, TaN, Al, Cu, Co, Ru, W, Au, or other suitable conductive materials. The gate metal 152 can be deposited by PVD, ALD, or CVD.

In FIG. 15, processing of the transistors one oh one is substantially complete. The top channel 105 of each transistor one oh one corresponds to a portion of the top semiconductor layer 104. In the various regions of differing fin density, the top channel 105 of each transistor one oh one has a profile in the Y direction as shown in FIGS. 9B-9D. The result is that each transistor 101 each of the various regions has a top channel 105 of functions well, contributing to overall improved performance of the transistors one oh one.

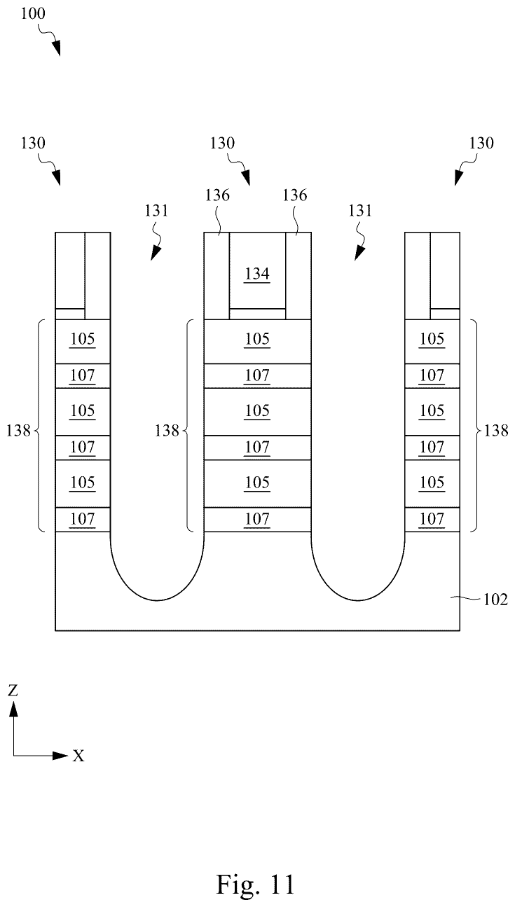

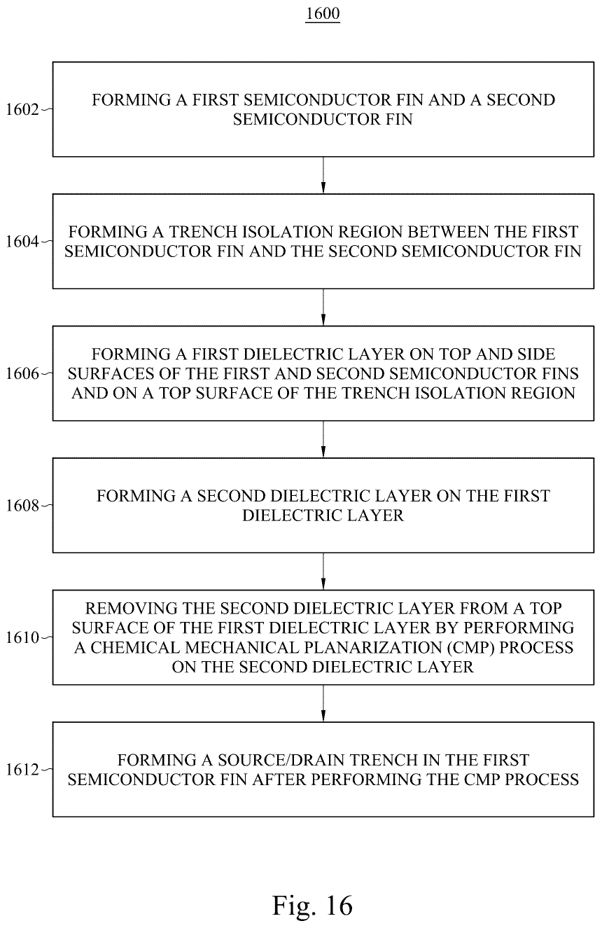

FIG. 16 is a flow diagram of a method 1600 for forming an integrated circuit, in accordance with some embodiments. The method 1600 can utilize the structures, processes, and systems described in relation to FIGS. 1-15. At 1602, the method 1600 includes forming a first semiconductor fin and a second semiconductor fin. One example of first and second semiconductor fins are the semiconductor fins 108 of FIG. 5. At 1604, the method 1600 includes forming a trench isolation region between the first semiconductor fin and the second semiconductor fin. One example of a trench isolation region is the trench isolation region 112 of FIG. 5. At 1606, the method 1600 includes forming a first dielectric layer on top and side surfaces of the first and second semiconductor fins and on a top surface of the trench isolation region. One example of a first dielectric layer is dielectric layer 126 of FIG. 5. At 1608, the method 1600 includes forming a second dielectric layer on the first dielectric layer. One example of a second dielectric layer is the dielectric layer 128 of FIG. 5. At 1610, the method 1600 includes removing the second dielectric layer from a top surface of the first dielectric layer by performing a chemical mechanical planarization (CMP) process on the second dielectric layer. At 1612, the method 1600 includes forming a source/drain trench in the first semiconductor fin after performing the CMP process. One example of a source/drain trench is the source/drain trench 130 one of FIG. 11.

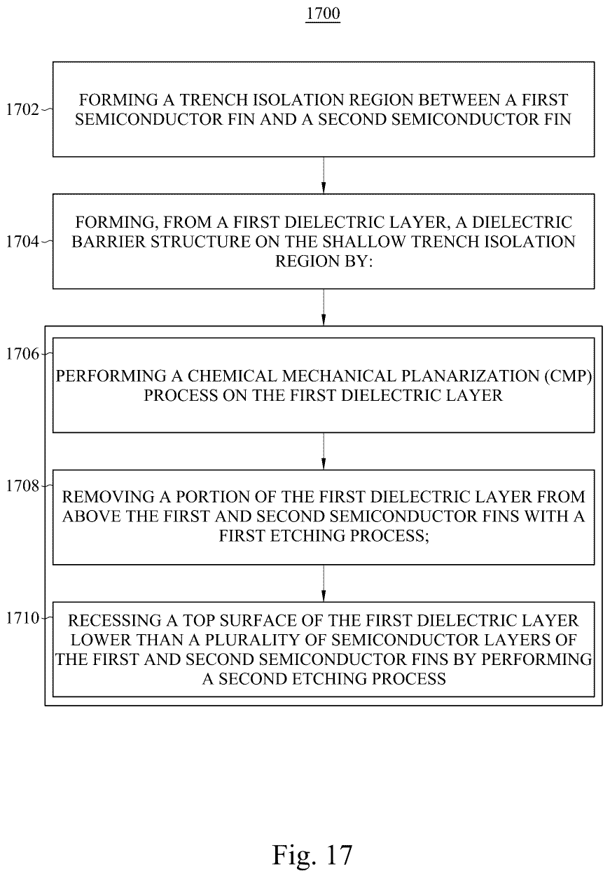

FIG. 17 is a flow diagram of a method 1700 for forming an integrated circuit, in accordance with some embodiments. The method 1700 can utilize the structures, processes, and systems described in relation to FIGS. 1-15. At 1702, the method 1700 includes forming a trench isolation region between a first semiconductor fin and a second semiconductor fin. One example of first and second semiconductor fins are the semiconductor fins 108 of FIG. 5. One example of a trench isolation region is the trench isolation region 112 of FIG. 5. At 1704, the method 1700 includes forming, from a first dielectric layer, a dielectric barrier structure on the shallow trench isolation region. At 1706, the method 700 includes forming the dielectric barrier structure by performing a chemical mechanical planarization (CMP) process on the first dielectric layer. One example of a dielectric barrier structure is the dielectric barrier structure 127 of FIG. 9A. At 1708, the method 1700 includes forming the dielectric barrier structure by removing a portion of the first dielectric layer from above the first and second semiconductor fins with a first etching process. At 1710, the method 1700 includes forming the dielectric barrier structure by recessing a top surface of the first dielectric layer lower than a plurality of semiconductor layers of the first and second semiconductor fins by performing a second etching process.

Embodiments of the disclosure provide a method for forming nanostructure transistors with reduced damage to the top nanostructure/channel of the transistors regardless of the local density of the semiconductor fins (OD) from which the transistors are formed. After formation of shallow trench isolation regions between fins, a process is performed to form dielectric barrier structures on the shallow trench isolation regions to protect the shallow trench isolation regions during subsequent processing steps. The process for forming the dielectric barrier structures includes depositing a dielectric layer on the shallow trench isolation regions and on the sidewalls and top surfaces of the semiconductor fins, and depositing a bottom antireflective coating (BARC) layer on the dielectric layer.

Embodiments of the present disclosure utilize a multistep etching process to remove the BARC layer and the dielectric layer from the tops of all fins without damaging the top layer of the fins, regardless of the local density of the fins. The multistep etching process includes performing a chemical mechanical planarization (CMP) on the BARC layer, followed by an etchback process that reduces the height of the BARC layer relative to the dielectric layer, and concluding with an etching process that removes the dielectric layer from the top of the fins. This results in transistors that have top channels without substantial damage, regardless of the local density of fins. This maintains a desired effective width of the top channels of the transistors, resulting in superior electrical characteristics, and better overall performance. Furthermore, this can improve wafer yields and overall function of integrated circuits and electronic devices in which the integrated circuits are embedded.

In some embodiments, a method includes forming a first semiconductor fin and a second semiconductor fin, forming a trench isolation region between the first semiconductor fin and the second semiconductor fin, and forming a first dielectric layer on top and side surfaces of the first and second semiconductor fins and on a top surface of the trench isolation region. The method includes forming a second dielectric layer on the first dielectric layer and removing the second dielectric layer from a top surface of the first dielectric layer by performing a chemical mechanical planarization (CMP) process on the second dielectric layer. The method includes forming a source/drain trench in the first semiconductor fin after performing the CMP process.

In some embodiments, a method includes forming a trench isolation region between a first semiconductor fin and a second semiconductor fin and forming, from a first dielectric layer, a dielectric barrier structure on the shallow trench isolation region by performing a chemical mechanical planarization (CMP) process on the first dielectric layer, removing a portion of the first dielectric layer from above the first and second semiconductor fins with a first etching process, and recessing a top surface of the first dielectric layer lower than a plurality of semiconductor layers of the first and second semiconductor fins by performing a second etching process.

In some embodiments, an integrated circuit includes a first area including a plurality of first semiconductor fins each including a plurality of stacked first semiconductor layers and each having a first width and a plurality of first trench isolation regions interleaved with the first semiconductor fins and each having a second width. The integrated circuit includes a second area including a plurality of second semiconductor fins each including a plurality of stacked second semiconductor layers and each having a third width and a plurality of second trench isolation regions interleaved with the second semiconductor fins and each having a fourth width. A ratio of the first width to the second width is greater than a ratio of the third width to the fourth width. A sidewall of a top first semiconductor layer of the first fins has a same angle relative to vertical as a sidewall of a top second semiconductor layer of the second fins.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor fin and a second semiconductor fin;
forming a trench isolation region between the first semiconductor fin and the second semiconductor fin;
forming a first dielectric layer on top and side surfaces of the first and second semiconductor fins and on a top surface of the trench isolation region;
forming a second dielectric layer on the first dielectric layer;
removing the second dielectric layer from a top surface of the first dielectric layer by performing a chemical mechanical planarization (CMP) process on the second dielectric layer; and
forming a source/drain trench in the first semiconductor fin after performing the CMP process.

2. The method of claim 1, further comprising recessing, after the CMP process, a top surface of the second dielectric layer to a level lower than the top surface of the first dielectric layer and above a top surface of the first semiconductor fin by performing a first etching process.

3. The method of claim 2, further comprising removing at least a portion of the first dielectric layer by performing a second etching process after the first etching process.

4. The method of claim 3, further comprising removing the second dielectric layer by performing a third etching process after the second etching process.

5. The method of claim 4, further comprising removing the first dielectric layer from the top surface of the first semiconductor fin and from a top surface of the second semiconductor fin by performing the third etching process.

6. The method of claim 5, comprising defining a dielectric barrier structure on the shallow trench isolation region by performing the third etching process, the dielectric barrier structure including a remnant of the first dielectric layer.

7. The method of claim 5, comprising forming a sacrificial gate structure crossing the first and second semiconductor fins after performing the third etching process and prior to forming source/drain trenches.

8. The method of claim 7, comprising forming, from the first semiconductor fin, a plurality of stacked channels of a transistor and a plurality of sacrificial semiconductor nanostructures interleaved with the channels by forming the source/drain trenches.

9. The method of claim 8, comprising:
removing the sacrificial semiconductor nanostructures; and
forming a gate metal of the transistor in place of the sacrificial semiconductor nanostructures.

10. The method of claim 9, comprising:
forming sacrificial dielectric nanostructures in place of the sacrificial semiconductor nanostructures;
removing the sacrificial dielectric nanostructures; and
forming the gate metal in place of the sacrificial dielectric nanostructures.

11. The method of claim 10, comprising removing the sacrificial dielectric nanostructures by performing an etching process while the dielectric barrier structure is present above the trench isolation region.

12. The method of claim 11, wherein the sacrificial dielectric nanostructures and the trench isolation region are a same dielectric material.

13. A method, comprising:
forming a trench isolation region between a first semiconductor fin and a second semiconductor fin;
forming, from a first dielectric layer, a dielectric barrier structure on the trench isolation region by:
performing a chemical mechanical planarization (CMP) process on the first dielectric layer;
removing a portion of the first dielectric layer from above the first and second semiconductor fins with a first etching process; and
recessing a top surface of the first dielectric layer lower than a plurality of semiconductor layers of the first and second semiconductor fins by performing a second etching process.

14. The method of claim 13, comprising performing a third etching process between the CMP process and the first etching process.

15. The method of claim 14, wherein:
performing the CMP process removes a portion of a second dielectric layer from the top surface of the first dielectric layer; and
performing the third etching process recesses a top surface of the second dielectric layer to a level lower than the top surface of the first dielectric layer.

16. The method of claim 15, wherein the second etching process entirely removes the second dielectric layer.

17. The method of claim 16, wherein the first dielectric layer is silicon nitride and the second dielectric layer is an organic polymer.

18. The method of claim 16, comprising forming a source drain region of a transistor in the first semiconductor fin after forming the dielectric barrier structure.

19. An integrated circuit, comprising:
a first area including:
a plurality of first semiconductor fins each including a plurality of stacked first semiconductor layers and each having a first width; and
a plurality of first trench isolation regions interleaved with the first semiconductor fins and each having a second width; and
a second area including:
a plurality of second semiconductor fins each including a plurality of stacked second semiconductor layers and each having a third width; and
a plurality of second trench isolation regions interleaved with the second semiconductor fins and each having a fourth width, wherein a ratio of the first width to the second width is greater than a ratio of the third width to the fourth width, wherein a sidewall of a top first semiconductor layer of the first semiconductor fins has a same angle relative to vertical as a sidewall of a top second semiconductor layer of the second semiconductor fins.

20. The integrated circuit of claim 19, comprising a dielectric barrier structure on one of the first trench isolation regions and having a top surface lower than a lowest first semiconductor layer of an adjacent first semiconductor fin.
